(19) United States
(12) Patent Application Publication
(10) Pub. No.: US 2025/0135510 A1
(43) Pub. Date: May 1, 2025

(54) SUBSTRATE TREATING APPARATUS AND SUBSTRATE TREATING METHOD

(71) Applicant: SEMES CO., LTD., Cheonan-si (KR)

(72) Inventors: Si Nae SONG, Hwaseong-si (KR); Ho Jin JEONG, Cheonan-si (KR); Kyung Min KIM, Cheonan-si (KR); Sung Bum PARK, Cheonan-si (KR); Dong Ho LIM, Seoul (KR); Soo Young PARK, Cheonan-si (KR)

(21) Appl. No.: 18/929,782

(22) Filed: Oct. 29, 2024

(30) Foreign Application Priority Data
Oct. 31, 2023 (KR) 10-2023-0148373

(51) Int. Cl. B08B 3/04; B08B 3/08; H01L 21/02

(52) U.S. Cl. CPC B08B 3/041; B08B 3/08; H01L 21/02057

(57) ABSTRACT

Disclosed is a substrate treating apparatus including: a substrate support unit for supporting and rotating a substrate; a liquid supply unit for supplying a treatment solution onto the substrate; a collection cup provided to surround the substrate support unit, and having a plurality of collection spaces for collecting a treatment solution scattered from the substrate; a lifting unit for changing a relative position between the collection cup and the substrate; and a controller for controlling the lifting unit to vary a relative height between the substrate and the collection cup in accordance with a process recipe for treating the substrate.

### CROSS-REFERENCE TO RELATED APPLICATIONS

This application claims priority to and the benefit of Korean Patent Application No. 10-2023-0148373 filed in the Korean Intellectual Property Office on Oct. 31, 2023, the entire contents of which are incorporated herein by reference.

### TECHNICAL FIELD

The present invention relates to a substrate treating apparatus and a substrate treating method.

### BACKGROUND ART

A semiconductor (or display) manufacturing process is a process for manufacturing semiconductor devices on a substrate (e.g., wafer), and include, for example, exposure, deposition, etching, ion implantation, and cleaning. In particular, various organic and inorganic foreign substances are present on the substrate. Therefore, it is very important to effectively remove the foreign matter on the substrate in order to improve the manufacturing yield.

To remove foreign substances, a cleaning process using a treatment solution (cleaning solution) is mainly used. The cleaning process may be performed by supplying the treatment solution to a top surface or a back surface of the substrate while rotating a spin chuck supporting the substrate, and after the cleaning process, a rinsing process using a rinse solution, a drying process using drying gas, and the like are performed.

On the other hand, it is necessary to collect the treatment solution supplied to the substrate for discharge or reuse. A collection container (cup or bowl) formed around the periphery of the substrate may be arranged to collect the treatment solution that is scattered from the substrate. In order to effectively collect the treatment solution, the collection container is raised to a position higher than the substrate in time with the supply of the treatment solution, and it is necessary to adjust the height of the collection container appropriately due to the different characteristics (height, speed) of the treatment solution scattered under various process conditions.

### SUMMARY OF THE INVENTION

The present invention has been made in an effort to provide a substrate treating apparatus and method capable of adjusting a height of a collection container according to process conditions.

The present invention has been made in an effort to provide a substrate treating apparatus and method capable of minimizing rebound of a treatment solution scattered from a substrate from a collection container.

The present invention has been made in an effort to provide a substrate treating apparatus and method capable of efficiently collecting a treatment solution.

The problem to be solved by the present invention is not limited to the above-mentioned problems, and the problems not mentioned will be clearly understood by those skilled in the art from the descriptions below.

An exemplary embodiment of the present invention provides a substrate treating apparatus including: a substrate support unit for supporting and rotating a substrate; a liquid supply unit for supplying a treatment solution onto the substrate; a collection cup provided to surround the substrate support unit, and having a plurality of collection spaces for collecting a treatment solution scattered from the substrate; a lifting unit for changing a relative position between the collection cup and the substrate; and a controller for controlling the lifting unit to vary a relative height between the substrate and the collection cup in accordance with a process recipe for treating the substrate

Further, the process recipe may include flow rate information of the treatment solution supplied to the substrate, and the controller may control the lifting unit based on the flow rate information of the treatment solution.

Further, the flow rate information of the treatment solution may include a first discharge section discharging the treatment solution at a first flow rate, and a second discharge section discharging the treatment solution at a second flow rate that is different from the first flow rate, and the controller may control the lifting unit such that, when the discharge section is switched from the first discharge section to the second discharge section, a height of the collection cup is also switched.

Further, the controller may control the lifting unit such that, when the first flow rate is less than the second flow rate, a height at which the collection cup collects the treatment solution in the first discharge section is lower than a height at which the collection cup collects the treatment solution in the second discharge section, and the controller may control the lifting unit such that, when the first flow rate is greater than the second flow rate, a height at which the collection cup collects the treatment solution in the first discharge section is greater than a height at which the collection cup collects the treatment solution in the second discharge section.

Further, the collection cup may be provided to surround the substrate support unit and includes a plurality of collection containers for collecting a substrate treatment solution, and the plurality of collection containers may have inlets for collecting the treatment solutions at different heights.

Further, the controller may control the lifting unit to increase a distance from the substrate to a top end of the inlet of the collection container when a flow rate of the treatment solution supplied to the substrate increases.

Further, the distance from the substrate to the top end of the inlet of the collection container may be 22±5 mm when the flow rate of the treatment solution is 500 cc/min or less, 27±5 mm when the flow rate of the treatment solution is 500 to 1000 cc/min, and 32±5 mm when the flow rate of the treatment solution is 1000 cc/min or more.

Further, the liquid supply unit may include: a nozzle for discharging the treatment solution supplied to the substrate; and a flow regulating valve controlled by the controller and for regulating a flow rate of a treatment solution supplied to the nozzle, and the controller controls the lifting unit in conjunction with control of the flow regulating valve.

Another exemplary embodiment of the present invention provides a substrate treating method including: rotating a substrate positioned within a collection cup; and liquid treating the substrate by supplying a treatment solution onto the substrate rotated within the collection cup, in which the liquid treating of the substrate includes changing a relative height between the substrate and the collection cup in accordance with treatment solution flow rate information of a process recipe for treating the substrate.

Further, the treatment solution flow rate information may include a first discharge section discharging the treatment solution at a first flow rate, and a second discharge section discharging the treatment solution at a second flow rate that is different from the first flow rate, and when the discharge section may be switched from the first discharge section to the second discharge section, a height of the collection cup is also switched.

Further, when the first flow rate is less than the second flow rate, a height at which the collection cup collects the treatment solution in the first discharge section may be lower than a height at which the collection cup collects the treatment solution in the second discharge section.

Further, when the first flow rate is greater than the second flow rate, a height at which the collection cup collects the treatment solution in the first discharge section may be greater than a height at which the collection cup collects the treatment solution in the second discharge section.

Further, the collection cup may be provided to surround the substrate support unit and includes a plurality of collection containers for collecting a substrate treatment solution, and the plurality of collection containers may have inlets for collecting the treatment solutions at different heights.

Further, the height of the collection cup may be switched to increase a distance from the substrate to a top end of the inlet of the collection container when a flow rate of the treatment solution supplied to the substrate increases.

Further, the distance from the substrate to the top end of the inlet of the collection container may be 22±5 mm when the flow rate of the treatment solution is 500 cc/min or less, 27±5 mm when the flow rate of the treatment solution is 500 to 1000 cc/min, and 32±5 mm when the flow rate of the treatment solution is 1000 cc/min or more.

Further, the switching of the height of the collection cup may be performed in conjunction with flow rate control of a flow regulating valve that regulates a flow rate of a treatment solution supplied to a nozzle discharging the treatment solution to the substrate.

Further, the process recipe may further include height information of the collection cup.

Still another exemplary embodiment of the present invention provides a substrate treating apparatus including: a substrate support unit for supporting and rotating a substrate; a nozzle for discharging a treatment solution to the substrate; a flow regulating valve for regulating a flow rate of a treatment solution supplied to the nozzle; a collection cup provided to surround the substrate support unit, and having a plurality of collection spaces for collecting a treatment solution scattered from the substrate; the collection cup being provided to surround the substrate support unit and including a collection container for collecting the treatment solution scattered from the substrate; a lifting unit for lifting the collection cup; and a controller for controlling the lifting unit to vary a relative height between the substrate and the collection cup based on flow rate information of the treatment solution supplied to the substrate, in which the controller controls the lifting unit to increase a distance from the substrate to a top end of the inlet of the collection space when the flow rate of the treatment solution supplied to the substrate increases, and controls the lifting unit to decrease the distance from the substrate to the top end of the inlet of the collection space when the flow rate of the treatment solution supplied to the substrate decreases.

Further, the flow rate information of the treatment solution may include a first discharge section discharging the treatment solution at a first flow rate, and a second discharge section discharging the treatment solution at a second flow rate that is different from the first flow rate, and the controller may control the lifting unit such that, when the discharge section is switched from the first discharge section to the second discharge section, a height of the collection cup is also switched, and the controller may control the lifting unit such that, when the first flow rate is less than the second flow rate, a height at which the collection cup collects the treatment solution in the first discharge section is lower than a height at which the collection cup collects the treatment solution in the second discharge section, and the controller may control the lifting unit such that, when the first flow rate is greater than the second flow rate, a height at which the collection cup collects the treatment solution in the first discharge section is greater than a height at which the collection cup collects the treatment solution in the second discharge section.

Further, the distance from the substrate to the top end of the inlet of the collection container is 22±5 mm when the flow rate of the treatment solution is 500 cc/min or less, 27±5 mm when the flow rate of the treatment solution is 500 to 1000 cc/min, and 32±5 mm when the flow rate of the treatment solution is 1000 cc/min or more.

According to the exemplary embodiment of the present invention, by setting the distance from the substrate to the top end of the inlet to be variable in accordance with changes in the flow rate of the treatment solution discharged from the nozzle, the collection efficiency of the treatment solution scattered from the substrate may be increased, and the overall process quality may be improved by optimizing the process at each operation.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a diagram illustrating a substrate treating apparatus according to an exemplary embodiment of the present invention.

FIG. 2 is a diagram schematically illustrating a liquid treating chamber of FIG. 1 according to the exemplary embodiment.

FIG. 3 is a graph illustrating a flow rate of a treatment solution.

FIG. 4 is a graph illustrating a change in height of a cup in response to a change in flow rate of a treatment solution.

FIG. 5A is a diagram illustrating a height of the cup in a first discharge section illustrated in FIG. 3.

FIG. 5B is a diagram illustrating a height of the cup in a second discharge section illustrated in FIG. 3.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

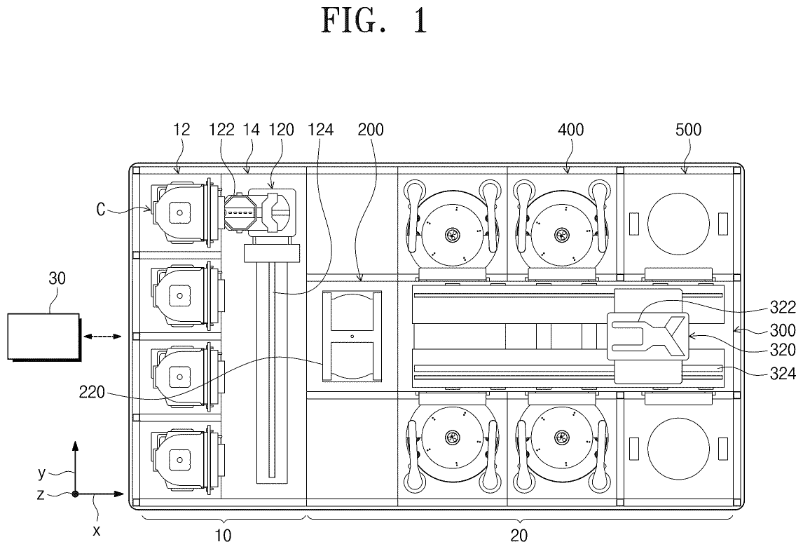

Hereinafter, an exemplary embodiment of the present invention will be described with reference to FIGS. 1 to 5B.

FIG. 1 is a diagram illustrating a substrate treating apparatus according to an exemplary embodiment of the present invention.

Referring to FIG. 1, a substrate treating apparatus includes an index module 10, a treating module 20, and a controller 30. When viewed from above, the index module 10 and the treating module 20 are disposed along one direction. Hereinafter, the direction in which the index module 10 and the treating module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the treating module 20, and accommodates the substrate W that has been completely treated in the treating module 20 in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The controller 30 may control the substrate treating apparatus. The controller 30 may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treatment recipe, for executing the process in each component according to various data and treatment conditions. Further, the user interface and the storage unit may be connected to the process controller. The treating recipe may be memorized in a storage medium in the storage unit, and the storage medium may be a hard disk, and may also be a portable disk, such as a CD-ROM or a DVD, or a semiconductor memory, such as a flash memory.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transport chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The index robot 320 includes a hand 322 on which the substrate W is placed, and the hand 322 may be provided to be movable forward and backward directions, rotatable about the third direction Z and movable along the third direction Z. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed to be spaced apart from each other along the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

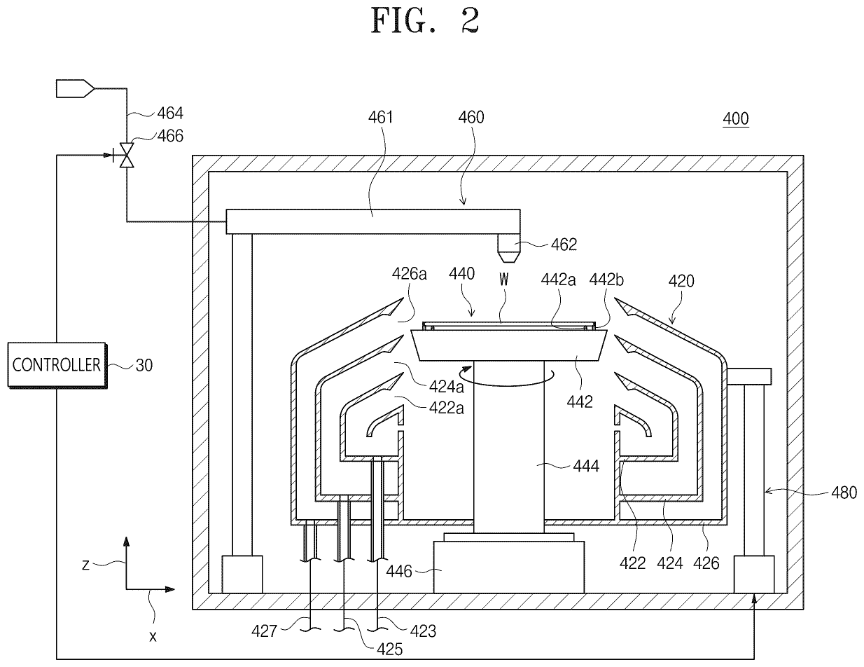

FIG. 2 is a diagram schematically illustrating the liquid treating chamber of FIG. 1 according to an exemplary embodiment.

Referring to FIG. 2, the liquid treating chamber 400 may include a housing 410, a cup 420, a support unit 440, a liquid supply unit 460, and a lifting unit 480.

The housing 410 may have an interior space where the substrate W is treated. The housing 410 may have a generally hexahedral shape. For example, the housing 410 may have a cuboidal shape. Additionally, the housing 410 may have an opening (not illustrated) through which the substrate W is loaded or unloaded. Additionally, the housing 410 may be equipped with a door (not illustrated) that selectively opens and closes the opening.

The cup 420 may have a barrel shape with an open top. The cup 420 has a treatment space, and the substrate W may be liquid-treated within the treatment space. The support unit 440 supports the substrate W in the treatment space. The liquid supply unit 460 supplies the treatment solution onto the substrate W supported on the support unit 440. The treatment solution may be provided in a plurality of types and may be supplied sequentially onto the substrate W. The lifting unit 480 adjusts a relative height between the cup 420 and the support unit 440.

In one example, the cup 420 may include a plurality of collection containers 422, 424, and 426. Each of the collection containers 422, 424, and 426 has a collection space of collecting the liquid used for the treating of the substrate. Each of the collection containers 422, 424, and 426 is provided in a ring shape surrounding the support unit 440. As the liquid treatment process proceeds, the treatment solution that is scattered by the rotation of the substrate W may flow into the collection space through inlets 422a, 424a, and 426a of the respective collection containers 422, 424, and 426. According to the example, the cup 420 includes a first collection container 422, a second collection container 424, and a third collection container 426. The first collection container 422 is disposed to surround the support unit 440, the second collection container 424 is disposed to surround the first collection container 422, and the third collection container 426 is disposed to surround the second collection container 424. The second inlet 424a of the second collection container 424 may be positioned above the first inlet 422a of the first collection container 422, and the third inlet 426a of the third collection container 426 may be positioned above the second inlet 424a.

Each of the collection containers 422, 424, and 426 has respective collection pipes 423, 425, and 427 extending below the bottom portion, allowing the treatment solution introduced into the respective collection containers through the inlets 422a, 424a, and 426a to be discharged. The discharged treatment solution may be reused through an external treatment solution regeneration system (not illustrated).

The support unit 440 includes a support plate 442 and a driving shaft 444. A top surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The drive shaft 444 is driven by a driver 446, is connected to the center of the bottom surface of the substrate W, and rotates the support plate 442 with respect to the central axis thereof.

In one example, the liquid supply unit 460 may include a nozzle 462, a liquid supply line 464, and a flow regulating valve 466 installed in the liquid supply line 464. The nozzle 462 may supply the treatment solution to the substrate W. The treatment solution may be a chemical, rinse solution, or organic solvent. The chemical may be a chemical having the nature of strong acid or strong base. In addition, the rinse solution may be pure. Furthermore, the organic solvent may be isopropyl alcohol (IPA). Additionally, the liquid supply unit 460 may include a plurality of nozzles 462, each of which may supply a different type of treatment solution. For example, one of the nozzles 462 may supply a chemical, another of the nozzles 462 may supply a rinse solution, and yet another of the nozzles 462 may supply an organic solvent. Further, the controller 30 may control the liquid supply unit 460 to supply an organic solvent from another one of the nozzles 462 to the substrate W after supplying a rinse solution from the other one of the nozzles 462. Thus, the rinse liquid supplied to the substrate W may be replaced with an organic solvent having low surface tension. The flow regulating valve 466 may be controlled by the controller 30.

The lifting unit 480 moves the cup 420 in the vertical direction. By the vertical movement of the cup 420, a relative height between the cup 420 and the substrate W is changed. This changes the collection containers 422, 424, and 426 for collecting the treatment solution depending on the type of liquid supplied to the substrate W, so that the liquids may be collected separately. Unlike the description, the cup 420 may be fixedly installed, and the lifting unit 480 may move the support unit 440 in the vertical direction. For reference, the lifting unit 480 is preferably driven by a motor rather than a cylinder drive to allow for fine adjustment of the height of the cup.

The controller 30 controls the lifting unit 480 to vary the relative height between the substrate W and the cup 420 according to the process recipe for treating the substrate, thereby minimizing the treatment solution rebounding from the collection container during the process of collecting the treatment solution that is scattered from the substrate and preventing back-contamination of the substrate. More specifically, the controller 30 may control the lifting unit 460 based on flow rate information of the treatment solution. The controller 30 may control the lifting unit 480 in conjunction with control of the flow regulating valve 466.

The process recipe may include flow rate information of the treatment solution supplied to the substrate. Additionally, the process recipe may additionally include a cup height. The process recipe may include various information, such as rotational speed of the support unit, liquid type, and time.

The controller 30 may control the lifting unit 480 based on the flow rate information of the treatment solution.

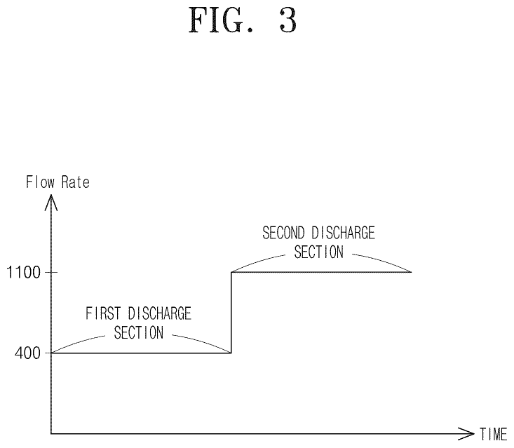

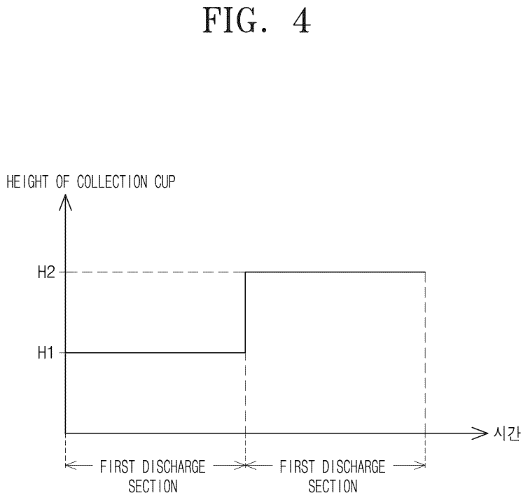

FIG. 3 is a graph illustrating a flow rate of a treatment solution, and FIG. 4 is a graph illustrating a change in height of a cup in response to a change in flow rate of a treatment solution. The graph shows the change in height of the cup under the condition in which the substrate rotates at the same speed.

Referring to FIGS. 3 and 4, the flow rate information of the treatment solution may include a first discharge section discharging the treatment solution at a first flow rate, and a second discharge section discharging the treatment solution at a second flow rate that is different from the first flow rate. When the discharge section is switched from the first discharge section to the second discharge section, the height of the cup 420 also switches.

The controller 30 may control the lifting unit 480 such that, when the first flow rate is less than the second flow rate, the height at which the cup 420 collects the treatment solution in the first discharge section is less than the height at which the cup 420 collects the treatment solution in the second discharge section, and the controller 30 may control the lifting unit 480 such that, when the first flow rate is greater than the second flow rate, the height at which the cup 420 collects the treatment solution in the first discharge section is greater than the height at which the cup 420 collects the treatment solution in the second discharge section. The controller 30 may control the lifting unit 480 such that a distance H from the substrate to the top end of the inlets 422a, 424a, and 426a of the collection container increases as the flow rate of the treatment solution supplied to the substrate increases.

In one example, the distance H from the substrate to the top end of the inlet of the collection container may be 22±5 mm when the flow rate of the treatment solution is 500 cc/min or less, 27±5 mm when the flow rate of the treatment solution is 500 to 1000 cc/min, and 32±5 mm when the flow rate of the treatment solution is 1000 cc/min or more.

The liquid treatment process performed in the liquid treating chamber 400 according to one exemplary embodiment of the present invention as described above will be described in detail as follows.

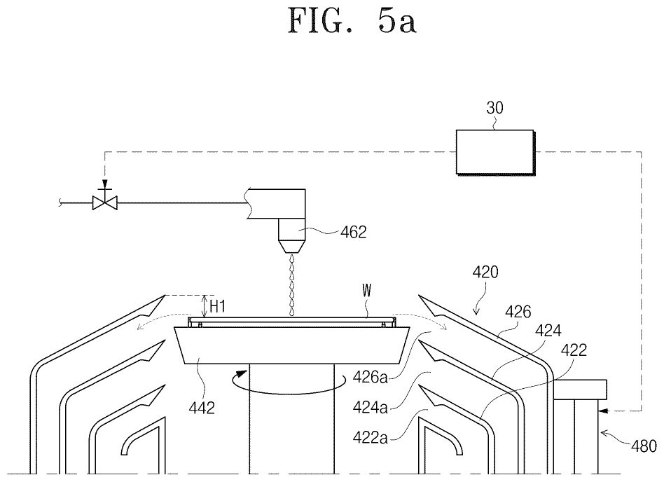

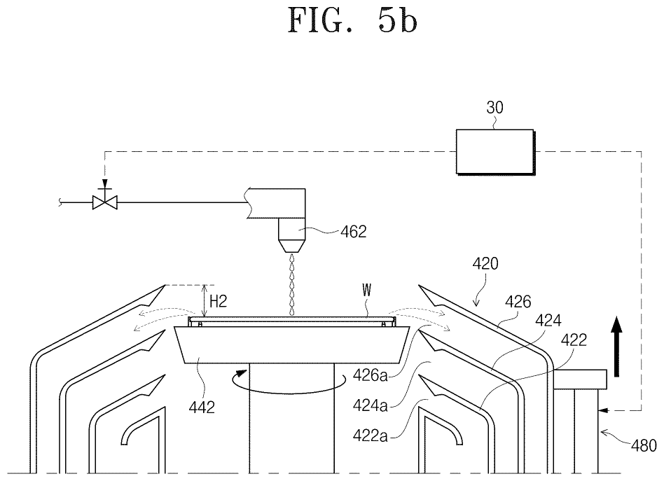

FIG. 5A is a diagram illustrating a height of the cup in the first discharge section illustrated in FIG. 3, and FIG. 5B is a diagram illustrating a height of the cup in the second discharge section illustrated in FIG. 3.

Referring to FIGS. 3, 5A, and 5B, the controller 30 controls the height of the cup so that one of the multiple inlets 422a, 424a, and 426a corresponds to a height of the horizontal plane of the substrate W, depending on the type of liquid in the process recipe. At this time, the controller 30 checks a discharge flow rate of the treatment solution and raises the cup to a set height corresponding to the corresponding discharge flow rate.

For example, in the first discharge section, the nozzle 462 discharges the treatment solution at a first flow rate of 400 cc/min, and in this case, the distance H from the substrate to the top end of the inlet of the collection container may be 22±5 mm. Further, when the discharge section is switched from the first discharge section to the second discharge section, the height of the cup 420 changes accordingly. That is, when the nozzle 462 discharges the treatment solution at a second flow rate of 1100 cc/min in the second discharge section, the distance H from the substrate to the top end of the inlet of the collection container may change to be 32±5 mm. Thus, the number of droplets scattered to the outside of the cup 420 may be reduced, and the possibility of contamination of the liquid treating chamber 400 may be reduced.

As the flow rate of the treatment solution discharged from the nozzle 462 increases, the range of droplets scattered from the substrate W may increase. Thus, when the relative height of the substrate W and the cup 420 is a fixed value, the collection efficiency of droplets scattered from the substrate may be reduced, and process failure due to scattering may occur. However, as in the present invention, by setting the distance H from the substrate to the top end of the inlet to vary according to the change in the flow rate of the treatment solution discharged from the nozzle 462, the collection efficiency of the treatment solution scattered from the substrate may be increased, and the overall process quality may be improved by optimizing the process at each step.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1.-8. (canceled)

9. A substrate treating method comprising:
rotating a substrate positioned within a collection cup; and
liquid treating the substrate by supplying a treatment solution onto the substrate rotated within the collection cup,
wherein the liquid treating of the substrate includes changing a relative height between the substrate and the collection cup in accordance with treatment solution flow rate information of a process recipe for treating the substrate.

10. The substrate treating method of claim 9, wherein the treatment solution flow rate information includes a first discharge section discharging the treatment solution at a first flow rate, and a second discharge section discharging the treatment solution at a second flow rate that is different from the first flow rate, and
when the discharge section is switched from the first discharge section to the second discharge section, a height of the collection cup is also switched.

11. The substrate treating method of claim 10, wherein when the first flow rate is less than the second flow rate, a height at which the collection cup collects the treatment solution in the first discharge section is lower than a height at which the collection cup collects the treatment solution in the second discharge section.

12. The substrate treating method of claim 11, wherein when the first flow rate is greater than the second flow rate, a height at which the collection cup collects the treatment solution in the first discharge section is greater than a height at which the collection cup collects the treatment solution in the second discharge section.

13. The substrate treating method of claim 9, wherein the collection cup is provided to surround the substrate support unit and includes a plurality of collection containers for collecting a substrate treatment solution, and
the plurality of collection containers has inlets for collecting the treatment solutions at different heights.

14. The substrate treating method of claim 13, wherein the height of the collection cup is switched to increase a distance from the substrate to a top end of the inlet of the collection container when a flow rate of the treatment solution supplied to the substrate increases.

15. The substrate treating method of claim 14, wherein the distance from the substrate to the top end of the inlet of the collection container is 22±5 mm when the flow rate of the treatment solution is 500 cc/min or less, 27±5 mm when the flow rate of the treatment solution is 500 to 1000 cc/min, and 32±5 mm when the flow rate of the treatment solution is 1000 cc/min or more.

16. The substrate treating method of claim 11, wherein the switching of the height of the collection cup is performed in conjunction with flow rate control of a flow regulating valve that regulates a flow rate of a treatment solution supplied to a nozzle discharging the treatment solution to the substrate.

17. The substrate treating method of claim 11, wherein the process recipe further includes height information of the collection cup.

18.-20. (canceled)
